(19) United States
(12) Patent Application Publication
(10) Pub. No.: US 2025/0029868 A1
(43) Pub. Date: Jan. 23, 2025

(54) LIFT PIN PROTECTION ASSEMBLY AND SUBSTRATE PROCESSING APPARATUS

(71) Applicant: EUGENE TECHNOLOGY CO., LTD., Yongin-si, Gyeonggi-do (KR)

(72) Inventors: Doo Yeol RYU, Yongin-si, Gyeonggi-do (KR); Ho Min CHOI, Yongin-si, Gyeonggi-do (KR); Wan Suk OH, Yongin-si, Gyeonggi-do (KR); Sung Gyun SON, Yongin-si, Gyeonggi-do (KR); Hyo Jin AHN, Yongin-si, Gyeonggi-do (KR); Sang Don LEE, Yongin-si, Gyeonggi-do (KR); Woo Young KANG, Yongin-si, Gyeonggi-do (KR); Se Yeong KIM, Yongin-si, Gyeonggi-do (KR); Ki Ho KIM, Yongin-si, Gyeonggi-do (KR); Koon Woo LEE, Yongin-si, Gyeonggi-do (KR)

(73) Assignee: EUGENE TECHNOLOGY CO., LTD., Yongin-si, Gyeonggi-do (KR)

(21) Appl. No.: 18/714,906

(22) PCT Filed: Sep. 22, 2022
(86) PCT No.: PCT/KR2022/014165

§ 371 Date: May 30, 2024

(30) Foreign Application Priority Data
Dec. 1, 2021 (KR) 10-2021-0170306

(51) Int. Cl. H01L 21/687; H01L 21/67

(52) U.S. Cl. CPC H01L 21/68785; H01L 21/67126; H01L 21/68742

(57) ABSTRACT

Provided is a substrate processing apparatus. The substrate processing apparatus includes a chamber in which a process with respect to a substrate is performed, a susceptor which is installed in the chamber and on which the substrate is placed, a plurality of lift pins passing through the susceptor to support the substrate, and a plurality of protection plugs protruding from a bottom surface of the susceptor to surround a portion of each of the lift pins protruding from the bottom surface of the susceptor.

### TECHNICAL FIELD

The present invention relates to a lift pin protection assembly and a substrate processing apparatus, and more particularly, to a lift pin protection assembly that is capable of preventing a lift pin from being contaminated and a substrate processing apparatus.

### BACKGROUND ART

In a semiconductor manufacturing process, lift pins are installed in a chamber and used to allow a semiconductor substrate to ascend or descend on a susceptor. A robot arm transfers the substrate into the chamber and places the substrate on the lift pins that protrude upward through the susceptor. Then, when the lift pins descend, the substrate is placed on an upper portion of the susceptor.

On the other hand, after the process of processing the substrate is completed, the lift pins ascend to lift the substrate from the susceptor, and the robot arm is inserted below the substrate to unload the processed substrate from the chamber. Thereafter, the lift pins descend to place the substrate on the robot arm, and the robot arm unloads the substrate from the chamber.

### DISCLOSURE OF THE INVENTION

### Technical Problem

The present invention provides a lift pin protection assembly capable of preventing a lift pin from being contaminated and a substrate processing apparatus.

The present invention also provides a lift pin protection assembly capable of preventing a lift pin from being exposed to a process gas and a substrate processing apparatus.

Further another object of the present invention will become evident with reference to following detailed descriptions and accompanying drawings.

### Technical Solution

According to an embodiment of the present invention, a substrate processing apparatus includes: a chamber in which a process with respect to a substrate is performed; a susceptor which is installed in the chamber and on which the substrate is placed; a plurality of lift pins passing through the susceptor to support the substrate; and a plurality of protection plugs protruding from a bottom surface of the susceptor to surround a portion of each of the lift pins protruding from the bottom surface of the susceptor.

The substrate processing apparatus may further include a protection cover having a flat plate, which is capable of being fixed to the bottom surface of the susceptor, wherein the protection cover may have a plurality of installation holes, in which the protection plugs are installed, respectively, and seating groove, which are respectively defined in upper portions of the installation grooves.

Each of the protection plugs may include: a tube-shaped body in which the lift pin is installed; and a support ring installed on an upper portion of the body so as to be accommodated in the seating groove, wherein an outer diameter of the support ring may be greater than an outer diameter of the body.

The protection cover may be fixed to the bottom surface of the susceptor through a plurality of coupling tools and have an outer diameter less than a diameter of the substrate.

Each of the protection plugs may include: a tube-shaped body in which the lift pin is installed; and a support ring installed on an upper portion of the body so as to be accommodated in a seating groove defined in a top surface of the susceptor, wherein an outer diameter of the support ring may be greater than an outer diameter of the body.

The susceptor may include: a plurality of lift pin holes vertically disposed so that the lift pins are installed, respectively; and coupling holes respectively disposed below the lift pin holes so as to be opened toward a lower portion of the susceptor, wherein each of the coupling holes has a diameter greater than that of each of the lift pin holes, wherein the protection plug may include: a tube-shaped body in which the lift pin is installed; and a support head installed on an upper portion of the body so as to be coupled to each of the coupling holes.

An outer diameter of an upper end of the body may be greater than an outer diameter of a lower end of the body and be less than a diameter of the coupling hole.

A distance from the bottom surface of the susceptor to a lower end of each of the protection plugs may be about 6 mm to about 10 mm.

According to an embodiment of the present invention, a lift pin protection assembly is installed on a susceptor to protrude from a bottom surface of the susceptor and surround a portion of a lift pin protruding from the bottom surface of the susceptor.

The lift pin protection assembly may further include a protection cover having a flat plate, which is capable of being fixed to the bottom surface of the susceptor, wherein the protection cover may have a plurality of installation holes, in which the protection plugs are installed, respectively, and seating groove, which are respectively defined in upper portions of the installation grooves.

### Advantageous Effects

According to the embodiment of the present invention, the protection plug may prevent the lift pin from being exposed to the process gas. In addition, the lifespan of the lift pin may be extended by easily replacing the protection plug if necessary.

### DESCRIPTION OF DRAWINGS

FIG. 1 is a schematic view of a substrate processing apparatus according to a first embodiment of the present invention;

FIG. 2 is a view of a protection cover and a protection plug illustrated in FIG. 1;

FIG. 3 is a schematic view of a substrate processing apparatus according to a second embodiment of the present invention;

FIG. 4 is a view of a protection cover and a protection plug illustrated in FIG. 3;

FIGS. 5 and 6 are schematic views of a protection plug according to a third embodiment of the present invention;

FIGS. 7 and 8 are schematic views of a protection plug according to a fourth embodiment of the present invention; and

FIGS. 9 and 10 are photographs illustrating a state of a lift pin after a process.

### BEST MODE

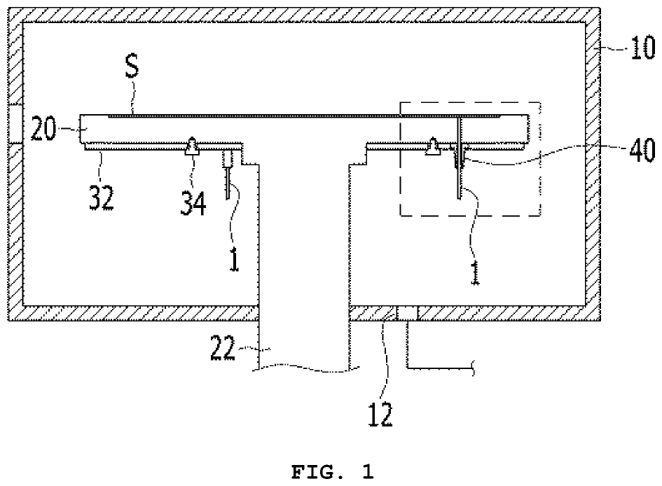

Hereinafter, exemplary embodiments of the present invention will be described in more detail with reference to FIGS. 1 to 10. The present invention may, however, be embodied in different forms and should not be constructed as limited to the embodiments set forth herein. Rather, these embodiments are provided so that this disclosure will be thorough and complete, and will fully convey the scope of the present invention to those skilled in the art. In the figures, the dimensions of layers and regions are exaggerated for clarity of illustration.

FIG. 1 is a schematic view of a substrate processing apparatus according to an embodiment of the present invention. A susceptor 20 is installed in an inner space of a chamber 10, and the chamber 10 has an inner space in which a process gas is supplied from the outside to perform a process on a substrate S. The chamber 10 has an exhaust port 12 communicating with the inner space and may discharge an unreacted gas and by-products in the inner space through an exhaust line connected to the exhaust port 12.

As illustrated in FIG. 1, the susceptor 20 is supported through a support shaft 22, and the substrate S is placed on an upper portion of the susceptor 20. The susceptor 20 may have a circular disk shape corresponding to the substrate S, but other shapes are also possible. The susceptor 20 may heat the substrate S to a preset temperature during the process, and a heater (not shown) may be installed inside the susceptor 20.

The substrate S may be supported by the lift pins 1, and each of the lift pins 1 may be installed to pass through a lift pin hole 21 defined in the susceptor 20 so as to be elevated within the lift pin hole 21. The lift pin 1 may be elevated by the elevation of the susceptor 20 or be elevated by a separate elevation mechanism, and since the elevation method of the lift pin 1 is a known technique, a detailed description thereof will be omitted.

As illustrated in FIG. 1, the lift pin 1 has a length greater than a thickness of the susceptor 20. In the state in which the lift pin 1 descends, the substrate S is placed on the upper portion of the susceptor 20. Here, an upper portion of the lift pin 1 is disposed in the lift pin hole 21, and a lower portion of the susceptor 20 protrudes downward. Although not shown, in the state in which the lift pin 1 ascends, the substrate S is lifted from the susceptor 20, and the upper portion of the lift pin 1 protrudes upward from the susceptor 20.

The protection cover 32 is installed on a bottom surface of the susceptor 20, and a plurality of coupling tools fix the protection cover 32 to the susceptor 20 through a plurality of through-holes defined in the protection cover 32. The protection cover 32 may have a shape corresponding to the susceptor 20 and may generally have a disk shape.

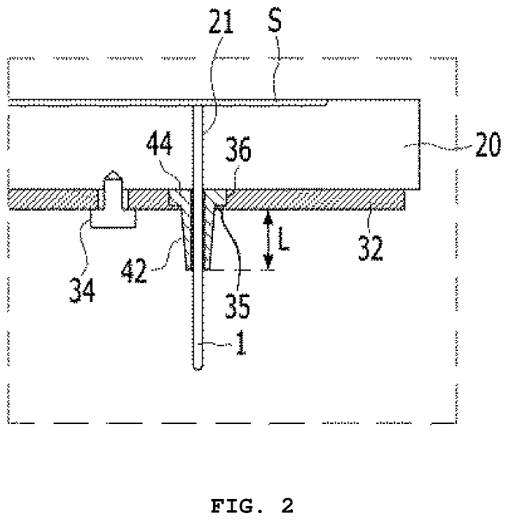

FIG. 2 is a view of the protection cover and a protection plug illustrated in FIG. 1. As illustrated in FIG. 2, the protection cover 32 has a plurality of installation holes 35 corresponding to the lift pin holes 21, respectively, and in the state in which the protection cover 32 is fixed to the susceptor 20, the lift pin holes communicate the installation holes 21, respectively. In addition, the protection cover 32 has a plurality of seating grooves 36 that are respectively defined above the installation holes 35, and each of the seating grooves 36 has a diameter greater than that of each of the installation holes 35. However, unlike this embodiment, the seating groove 36 may have a shape of a hole inclined (tapered) from an upper end to a lower end thereof.

A protection plug is inserted and installed in the installation hole 35 to surround a portion of the lift pin 1 protruding to the lower portion of the susceptor 20. The protection plug is provided with a tube-shaped body 42 and a support ring 44 connected to an upper portion of the body 42. The lift pin 1 is installed in the body 42, and the support ring 44 supports the body 35 in a state of being in the seating groove 36. An outer diameter of the support ring 44 is greater than an outer diameter of the body 42.

Specifically, an operator may install the protection plug on the protection cover 32 in a manner in which the protection plug is fitted into the installation groove 35 to accommodate (couple) the support ring 44 in the seating groove 36. Here, the installation of the protection plug may be completed in a manner in which the protection cover 32 is fixed to the susceptor 20 through the coupling tool 34. The protection plug surrounds a portion of the lift pin 1 protruding to the lower portion of the susceptor 20, and a distance L from a bottom surface of the susceptor 20 to a lower end of the protection plug may be about 6 mm to about 10 mm.

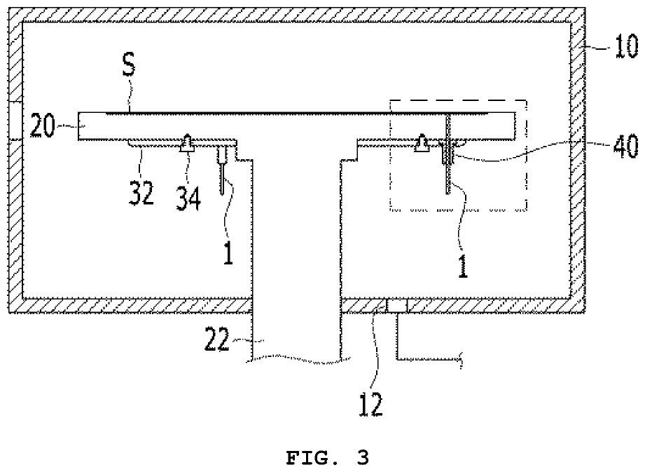

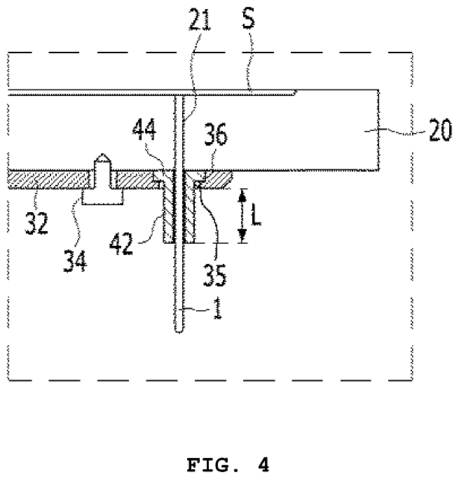

FIG. 3 is a schematic view of a substrate processing apparatus according to a second embodiment of the present invention, and FIG. 4 is a view of a protection cover and a protection plug illustrated in FIG. 3. The above-described protection cover 32 illustrated in FIGS. 1 and 2 has the diameter greater than that of the substrate S to cover the entire rear surface of the susceptor 20. On the other hand, a protection cover 32 illustrated in FIGS. 3 and 4 has a diameter less than that of a substrate S to cover a portion of a rear surface of the susceptor 20, and other structures and functions are the same.

Since the protection cover 32 is in contact with the rear surface of the susceptor 20 to serve as a heat sink that reduces a temperature of the susceptor 20, a size of the protection cover 32 may be adjusted as necessary. In addition, in this embodiment, although the protection cover 32 has been described in a disk shape, when considering that the protection cover 32 is used for fixing the protection plug to a lower portion of the susceptor 20, the protection cover 32 may have a plurality of branch shapes extending radially toward a lift pin hole 21 with respect to a center of the susceptor 20 such as a ‘+’ shape.

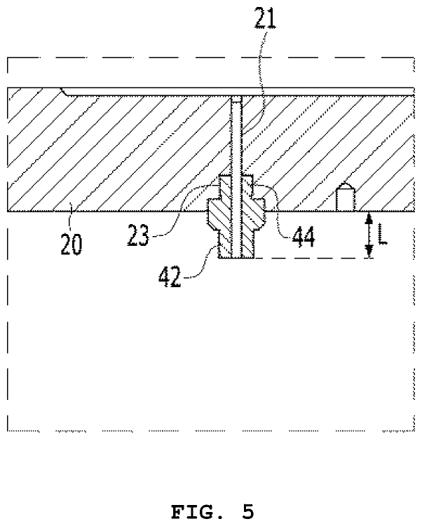

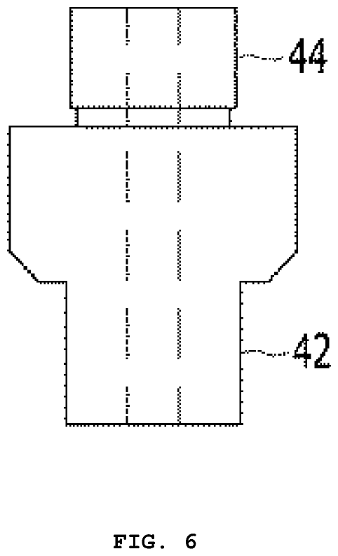

FIGS. 5 and 6 are schematic views of a protection plug according to a third embodiment of the present invention. As illustrated in FIG. 5, a protection cover may be omitted, and a protection plug may be directly fixed and installed to a susceptor.

A susceptor 20 has a plurality of coupling holes 23 that are respectively defined under lift pin holes 21, and the coupling holes 23 are opened toward a lower portion of the susceptor 20. Each of the coupling hole 23 has a diameter greater than that of each of the lift pin holes 21, and a screw thread may be disposed on an inner circumferential surface of the coupling hole 23.

The protection plug is provided with a tube-shaped body 42 and a support head 44 connected to an upper portion of the body 42. A lift pin 1 is installed in the body 42, and the support head 44 supports the body 42 in a state of being coupled to the coupling hole 23 through a screw thread disposed on an outer circumferential surface thereof. An outer diameter of an upper end of the body 42 is larger than that of a lower end thereof and is greater than a diameter of the coupling hole 23.

Specifically, an operator may fix a protection plug to a susceptor 20 in a manner in which a support head 44 of the protection plug is screw-coupled to the coupling hole 23, and in a state in which an upper end of the body 42 is in contact with a bottom surface of the susceptor 20, the protection plug may surround a portion of the lift pin 1 protruding to a lower portion of the susceptor 20, and a distance L from the bottom surface of the susceptor 20 to a lower end of the protection plug may be about 6 mm to about 10 mm.

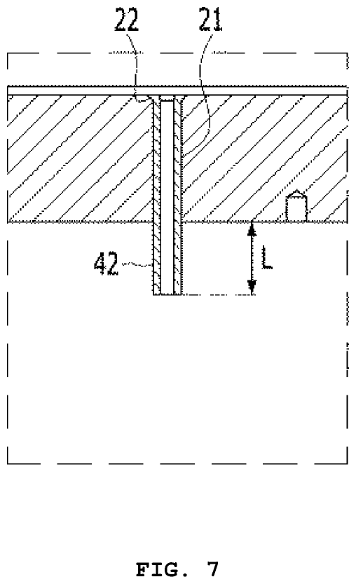

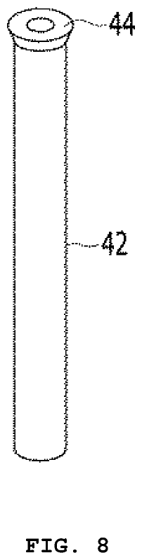

FIGS. 7 and 8 are schematic views of a protection plug according to a fourth embodiment of the present invention. As illustrated in FIG. 7, a susceptor 20 has a plurality of seating grooves 22 that are respectively defined in upper portions of lift pin holes 21, and each of the seating grooves 22 is opened toward an upper portion of the susceptor 20. The seating groove 22 has a shape of a hole inclined (tapered) from an upper end to a lower end thereof, but unlike this embodiment, the seating groove 22 may have a diameter greater than that of a lift pin hole 21 and may have a stepped shape.

The protection plug is provided with a tube-shaped body 42 and a support ring 44 connected to an upper portion of the body 42. The lift pin 1 is installed in the body 42, and the support ring 44 supports the body 42 in a state of being in the seating groove 22. An outer diameter of the support ring 44 is greater than an outer diameter of the body 42.

Specifically, an operator may fix a protection plug to a susceptor 20 in a manner in which the protection plug is fitted into the lift pin hole 21 to allow a support ring 44 to be accommodated (coupled) in the seating groove 22, and in a state in which an upper end of the support ring 44 is disposed at substantially the same height as a top surface of the susceptor 20, the protection plug may surround a portion of the lift pin 1 protruding to a lower portion of the susceptor 20, and a distance L from the bottom surface of the susceptor 20 to a lower end of the protection plug may be about 6 mm to about 10 mm.

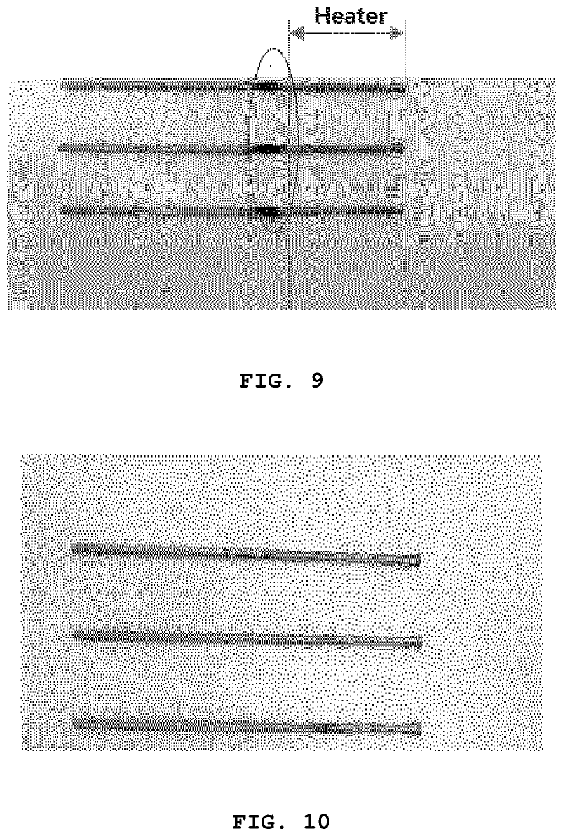

FIGS. 9 and 10 are photographs illustrating a state of the lift pin 1 after the process.

FIG. 9 illustrates a state of

the lift pin 1 after the process in a state in which the protection plug is not installed. Referring to FIG. 9, foreign substances (or black powder) generated due to a reaction gas during the process are attached to the lift pin 1 (indicated by a red circle), and the foreign substances become obstacles when the lift pin 1 is elevated along the lift pin hole 21 or is separated from the lift pin 1 to cause contamination of the inside of the chamber 10 and the substrate S.

Particularly, the foreign substances are not attached to an entire exposure section of the lift pin 1 exposed to a reaction gas during the process, but attached to only a partial section (about 6 mm to about 10 mm) disposed below the susceptor (or heater) 20.

FIG. 10 illustrates a state of the lift pin 1 after the process in a state in which the protection plug is installed. The protection plug was installed in consideration of the fact that the foreign substances are attached to only the portion (about 6 mm to about 10 mm) of the lift pin 1 (see FIGS. 2 and 4), and in consideration of this point, a distance from the bottom surface 20 to the lower end of the protection plug was adjusted to about 6 mm to about 10 mm. As a result, in the process, the partial section of the lift pin 1 were restricted so as not to be exposed to the reaction gas, and referring to FIG. 10, the foreign substances attached to the lift pin 1 were not found.

Although the present invention is described in detail with reference to the exemplary embodiments, the invention may be embodied in many different forms. Thus, technical idea and scope of claims set forth below are not limited to the preferred embodiments.

### INDUSTRIAL APPLICABILITY

The present invention can be applied to various types of semiconductor manufacturing facilities and manufacturing methods.

1. A substrate processing apparatus comprising:
a chamber in which a process with respect to a substrate is performed;
a susceptor which is installed in the chamber and on which the substrate is placed;
a plurality of lift pins passing through the susceptor to support the substrate; and
a plurality of protection plugs protruding from a bottom surface of the susceptor to surround a portion of each of the lift pins protruding from the bottom surface of the susceptor.

2. The substrate processing apparatus of claim 1, further comprising a protection cover having a flat plate, which is capable of being fixed to the bottom surface of the susceptor,
wherein the protection cover has a plurality of installation holes, in which the protection plugs are installed, respectively, and seating groove, which are respectively defined in upper portions of the installation grooves.

3. The substrate processing apparatus of claim 2, wherein each of the protection plugs comprises:
a tube-shaped body in which the lift pin is installed; and
a support ring installed on an upper portion of the body so as to be accommodated in the seating groove,
wherein an outer diameter of the support ring is greater than an outer diameter of the body.

4. The substrate processing apparatus of claim 2, wherein the protection cover is fixed to the bottom surface of the susceptor through a plurality of coupling tools and has an outer diameter less than a diameter of the substrate.

5. The substrate processing apparatus of claim 1, wherein each of the protection plugs comprises:
a tube-shaped body in which the lift pin is installed; and
a support ring installed on an upper portion of the body so as to be accommodated in a seating groove defined in a top surface of the susceptor,
wherein an outer diameter of the support ring is greater than an outer diameter of the body.

6. The substrate processing apparatus of claim 1, wherein the susceptor comprises:
a plurality of lift pin holes vertically disposed so that the lift pins are installed, respectively; and
coupling holes respectively disposed below the lift pin holes so as to be opened toward a lower portion of the susceptor, wherein each of the coupling holes has a diameter greater than that of each of the lift pin holes,
wherein the protection plug comprises:
a tube-shaped body in which the lift pin is installed; and
a support head installed on an upper portion of the body so as to be coupled to each of the coupling holes.

7. The substrate processing apparatus of claim 6, wherein an outer diameter of an upper end of the body is greater than an outer diameter of a lower end of the body and is less than a diameter of the coupling hole.

8. The substrate processing apparatus of claim 1, wherein a distance from the bottom surface of the susceptor to a lower end of each of the protection plugs is about 6 mm to about 10 mm.

9. A lift pin protection assembly installed on a susceptor to protrude from a bottom surface of the susceptor and surround a portion of a lift pin protruding from the bottom surface of the susceptor.

10. The lift pin protection assembly of claim 9, further comprising a protection cover having a flat plate, which is capable of being fixed to the bottom surface of the susceptor,
wherein the protection cover has a plurality of installation holes, in which the protection plugs are installed, respectively, and seating groove, which are respectively defined in upper portions of the installation grooves.

11. The lift pin protection assembly of claim 9, wherein each of the protection plugs comprises:
a tube-shaped body; and
a support ring installed on an upper portion of the body so as to be accommodated in a seating groove defined in a top surface of the susceptor,
wherein an outer diameter of the support ring is greater than an outer diameter of the body.

12. The lift pin protection assembly of claim 9, wherein each of the protection plugs comprises:
a tube-shaped body in which the lift pin is installed; and
a support head installed on an upper portion of the body and coupled to a coupling hole which is defined in the susceptor and is opened toward a lower portion of the susceptor.

13. The lift pin protection assembly of claim 9, wherein a distance from the bottom surface of the susceptor to a lower end of each of the protection plugs is about 6 mm to about 10 mm.
